(19) United States
(12) Patent Application Publication
(10) Pub. No.: US 2010/0173502 A1
(43) Pub. Date: Jul. 8, 2010

(54) LOW k1 HOLE PRINTING USING TWO INTERSECTING FEATURES

(76) Inventor: Michael Francis PAS, Richardson, TX (US)

Correspondence Address: TEXAS INSTRUMENTS INCORPORATED, P O BOX 655474, M/S 3999, DALLAS, TX, 75265, US

(21) Appl. No.: 12/349,617

(22) Filed: Jan. 7, 2009

(51) Int. Cl. H01L 21/00; G03B 27/42

(52) U.S. Cl. 438/795; 355/53; 257/E21.001

(57) ABSTRACT

A method of forming one or more features during semiconductor device fabrication can comprise exposing a photosensitive layer to a first pattern at an exposure energy which is insufficient to fully expose the photosensitive layer, then exposing the photosensitive layer to a second pattern at an exposure energy which is insufficient to fully expose the photosensitive layer At an intersection of the first and second patterns, the energy does received during the first and second exposure is sufficient to fully expose the photosensitive layer.

### FIELD OF THE INVENTION

This invention relates to the field of semiconductor device manufacture, and more particularly to photolithographic techniques for printing features during the formation of a semiconductor device.

### BACKGROUND OF THE INVENTION

Semiconductor device manufacture employs a number of processing techniques to form repetitive patterns across a surface of a semiconductor wafer, and photolithography (optical lithography) is generally used in some aspect in each technique. To form a feature using photolithography, a layer is formed over the semiconductor wafer then a photosensitive photoresist (resist) is formed over the layer to be etched. A mask or reticle (hereinafter collectively, “reticle”), which can comprise an etched pattern on a quartz substrate, an attenuated mask, an alternating phase shift mask, etc., is interposed between the photoresist and a light source. The light source is blocked by the pattern at unetched reticle locations, while the light source is allowed through at etched reticle locations to fall on the photoresist. Exposure to light alters the chemical makeup of the resist, and a developer is used to remove exposed resist locations (if a positive tone resist is used) or unexposed resist locations (if a negative tone resist is used) which exposes the layer to be etched on the wafer. An etch process is then used to remove the layer to be etched from the wafer at the exposed locations.

As feature densities increase with continuing device generations, problems arise with the use of photolithography. For example, scaling for each generational device node requires printing features such as contact holes or via openings (hereinafter collectively, “via openings”) and studs or posts (hereinafter collectively, “posts”) which are 50% smaller in two-dimensional area and 70% smaller in one dimension. An eventual result of ever-decreasing feature sizes is that the via openings and studs become smaller than the wavelength of the light source used to form them, which is currently 193 nanometers (nm). Printing features at a proportionality constant equaling 0.4 k₁ or less is particularly difficult. A proportionality constant k₁ indicates the difficulty of printing a feature, and is determined by the formula R=k₁λ/NA, where “R” is the resolution, “λ” is the wavelength of light, and “NA” is the numerical aperture. As k₁ decreases, a feature becomes increasingly difficult to print.

Various resolution enhancement techniques (RETs) have been used to extend the life of current photolithography equipment and methods. For example, sub-resolution assist features (SRAFs) can be formed on the reticle which do not print in the photoresist but provide additive or subtractive influence on the wavelength of the light source through the reticle to improve the printed image to produce features smaller than the light source wavelength. Still, producing features at small proportionality constants is difficult.

Other photolithographic techniques to improve printability of small features would be desirable.

### SUMMARY OF THE EMBODIMENTS

An embodiment of a method used to form a semiconductor device comprises exposing first portions of a photosensitive layer to a light source during only a first exposure with an energy which is insufficient to fully expose the photosensitive layer, and exposing second portions of the photosensitive layer to the light source during only a second exposure with an energy which is insufficient to fully expose the photosensitive layer. Third portions of the photosensitive layer are exposed to the light source during both the first and second exposures. An energy received by the third portions of the photosensitive layer during the first and second exposures is sufficient to fully expose the photosensitive layer. The light source used during at least one of the first and second exposures can be subject to an advanced illumination technique.

In another embodiment of the invention, a method used to form a semiconductor device comprises using a light source to expose a first feature having a length and a width during a first exposure onto a photosensitive layer which overlies a layer to be etched. The length of the first feature is longer than the width of the first feature. An energy of the light source is insufficient to fully expose the photosensitive layer during the first exposure. Subsequent to exposing the first feature, the light source is used to expose a second feature having a length and a width during a second exposure onto the photosensitive layer. The length of the second feature is longer than the width of the second feature, and an energy of the light source is insufficient to fully expose the photosensitive layer during the second exposure. Portions of the photosensitive layer are removed to expose first portions of the layer to be etched and leaving portions of the photosensitive layer to cover second portions of the layer to be etched. During at least one of the first and second exposures, the light is subject to an advanced illumination technique.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIGS. 1-5 are plan views depicting an embodiment of the invention to form contact openings or via openings;

FIGS. 6-10 are cross sections depicting an embodiment to form conductive structures within the contact openings or via openings formed by the process depicted in FIGS. 1-5;

FIG. 11 depicts a dipole illuminator which can be used with an embodiment of the invention;

FIGS. 12-14 are plan views depicting an embodiment of the invention to form isolated contact openings or via openings; and

FIGS. 15-17 are plan views depicting an embodiment of the invention to form random contact openings or via openings.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Embodiments of the present teachings can comprise a double print process which uses two exposures of the photoresist to form selected features such as via openings or posts. Each exposure can be performed using a different reticle and can use a light source which is less than sufficient to fully expose the resist, but the additive effect of the double print process sufficiently alters the chemical makeup of the resist receiving light during both exposures.

Reference will now be made in detail to the present embodiments (exemplary embodiments) of the invention, examples of which are illustrated in the accompanying drawings. Wherever possible, the same reference numbers will be used throughout the drawings to refer to the same or like parts.

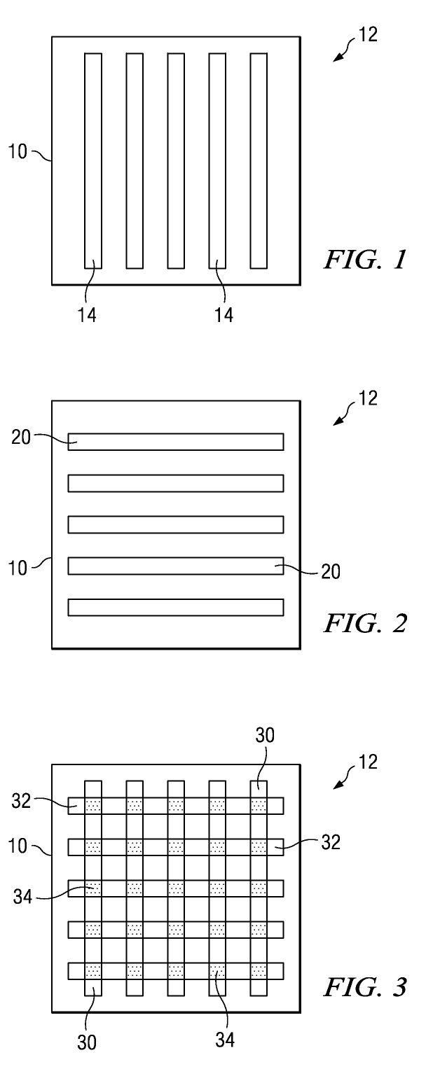

A first embodiment of the inventive process for forming via openings within a dielectric layer is depicted in the plan views of FIGS. 1-5. In this specific example, a circular via opening having a diameter of about 42 nm is to be formed using a light source having a wavelength of 193 nm. Thus the diameter of the feature is about 0.22 times the wavelength of the light source, and the proportionality constant k₁ of the resulting structure is about 0.26. Forming a circular or oval feature with a diameter of less than the wavelength of light can be formed using various resolution enhancement techniques, but forming such a structure at a k₁ of 0.40 or less is difficult, and increases significantly in difficulty with further decreases in k₁.

A semiconductor wafer substrate assembly is provided, which can comprise features such as shallow trench isolation, doped regions, transistors, and an underlying layer to be etched. In FIG. 1, a positive photoresist layer 10 is formed over the semiconductor wafer substrate assembly, and the semiconductor wafer substrate assembly and photoresist layer 10 together form structure 12. FIG. 1 further depicts portions 14 of photoresist layer which have been exposed to a 193 nm light source through a reticle. In this embodiment, the photoresist can be positive resist with portions 14 being exposed to light in a line-shaped pattern. Thus portions 14 define a “line space,” because if the pattern were fully exposed and etched, a line-shaped space would result. In contrast with conventional processes, the light source exposure energy (i.e. exposure dose) is insufficient to fully convert the chemical makeup of the resist. For example, for a positive photoresist layer which is 2,500 angstroms thick, a light source having wavelength of 193 nm and an energy of between about 20 mJ (millijoules) to about 50 mJ can be required to fully expose the resist such that it will be removed by a developer. In the present embodiment, a 193 nm light source having an exposure energy of between about 55% and about 95%, more particularly between about 60% and about 90%, and most particularly about 75%, of that required to fully develop the resist can be used. A hard bake may be included in the process if necessary or desired.

Exposed portions 14 of the resist comprise a number of line spaces. The reticle can be manufactured such that the width of each line space exposed on the photoresist is about 42 nm, with the length being at least 5 times the width, for example between about 150 nm and about 250 nm long. An exemplary feature pitch is between about 80 nm and about 120 nm.

After exposing the photoresist layer 10 to the light source, a second exposure is performed using a second reticle. FIG. 2 depicts an exemplary exposure pattern 20 produced on the photoresist layer 10 by the second exposure. As with the first exposure, the exposure energy of the light source is insufficient to fully expose the photoresist layer such that the resist exposed to the pattern 20 alone would not be completely removed by a developer. The same light source exposure energy of the first exposure can be used, for example between about 55% and about 95%, more particularly between about 60% and about 90%, and most particularly about 75%, of that required to fully convert the photoresist to a state which is soluble in a developer.

FIG. 3 depicts the combined effects of the first and second exposures. Regions 30 are exposed during only the first exposure, regions 32 are exposed during only the second exposure, and regions 34 are exposed during both the first and second exposure. The two combined exposures are sufficient to fully expose regions 34, which become fully soluble in a developer.

FIG. 4 depicts the resist portions 40 that are at the intersection of line spaces 14, 20, and which are exposed to both the first and second exposures. While the reticle resulting pattern of doubly exposed resist portions 40 is square, it is difficult to completely remove the resist in the corners of small features such as the 42 nm square features depicted. Rinsing the photoresist layer in a developer may only incompletely remove the exposed resist to produce the openings 50 with rounded corners as depicted in FIG. 5. However, the features formed are more square than features formed using a single two-dimensional reticle pattern, and thus can be used to form features having a larger surface area than can be formed with conventional techniques. Using a reticle which exposes line space widths of 42 nm in perpendicular directions as depicted in FIG. 3 can form openings 50 as depicted in FIG. 5 with a diameter of between about 35 nm and about 45 nm.

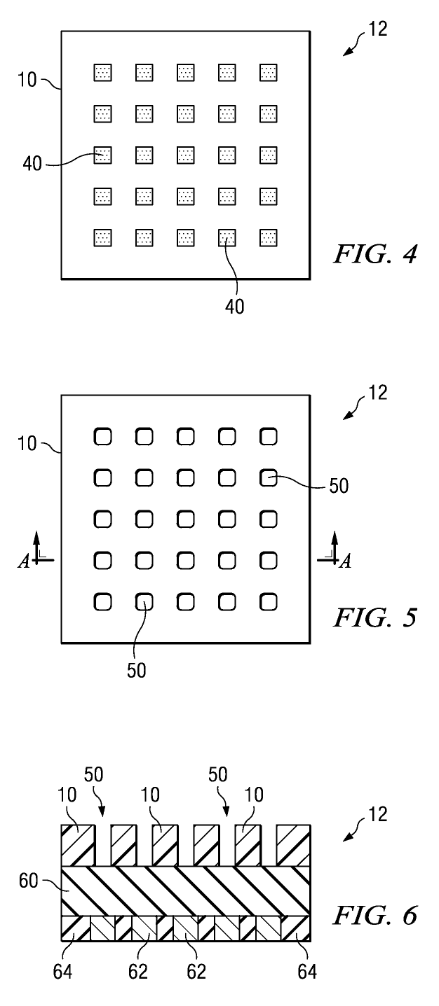

After forming the via openings 50 as depicted in FIG. 5, an etch can be performed on the layer to be etched, for example dielectric layer 60 as depicted in FIG. 6, which is a cross section of FIG. 5 along A-A. The etch of layer 60 can be performed using dry (plasma) etch process which transfers the via openings 50 into the layer to be etched 60 to result in the FIG. 7 structure. The etch of layer 60 can be used to expose an underlying layer 62 such as a first metal conductor layer formed in dielectric base layer 64. The photoresist 10 can then be removed using an ashing process and/or a wet clean to result in the structure of FIG. 8. Subsequently, a second layer of metal conductor 90 can be formed over the dielectric layer and within the openings in the dielectric layer as depicted in FIG. 9 to contact the first metal conductor layer. The second layer of metal conductor 90 which overlies the dielectric 60 layer can then be removed such as by chemical mechanical polishing (CMP) to provide a plurality of vias arranged in a grid pattern. The via openings in the photoresist and within the dielectric layer, and thus the resulting metal vias, can be formed at a k₁ of 0.4 or below, for example for logic applications.

Thus the process described above can be used to form a via opening at a dimension which is below the minimum resolvable by conventional processes which use a single print exposure, for example because a width of a line space can be printed at a practical resolution which is less than a practical resolution of a two-dimensional feature such as a diameter of a printed circle or oval. That is, it is easier to decrease the width of a printed line space having a given length than it is to decrease the diameter of a printed circle. For example, for a given device node and conventional technology, it may be possible to print a line space which is 42 nm wide while a minimum via opening may be 60 nm in diameter. With embodiments of the present invention, a via opening of between about 42 nm to 50 nm, and more particularly between about 42 nm and about 45 nm, can result, and therefore can provide a method for forming a via opening having a diameter of up to 30% smaller than conventional technology.

Another feature of the process described above and depicted in FIGS. 1-5 is that the process can benefit from optimized illumination, for example through being subject to at least one of polarization and dipole illumination, or another advanced illumination technique which provides a minimum line space pitch. This is particularly true when exposure is performed at high numerical aperture (NA), for example an NA>1 Using these enhancements, features can be printed at a k₁ of 0.30 or less. These illumination conditions can be selected to maximize the feature density. Polarized illumination systems are available commercially, for example from Nikon Corporation of Tokyo, Japan.

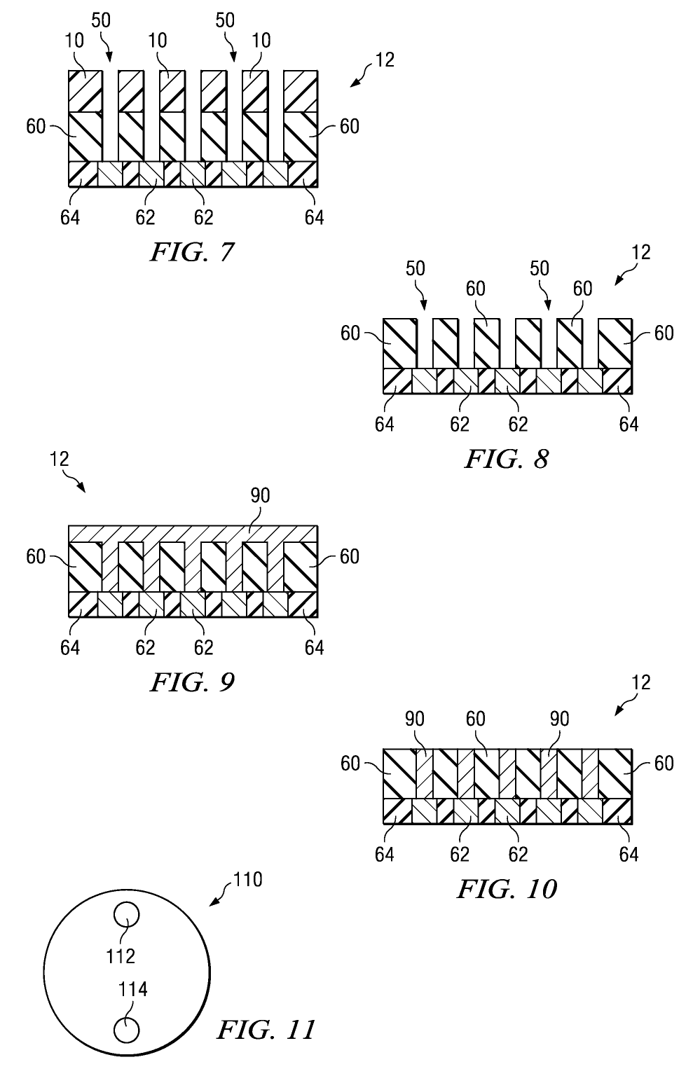

Dipole illumination is particularly useful with conventional technology when printing a single row or column of features, such as one column of the circular openings 50 of FIG. 5. A dipole illuminator 110 having a first aperture 112 and second aperture 114 is depicted in FIG. 11. A structure comprising one row or one column of features can be formed, for example, when forming a single string of contact openings for a flash memory device. With conventional technology, dipole illumination is not used when printing a grid of circular features formed in both x- and y-directions such as that depicted in FIG. 5 because the features are typically printed using a single reticle exposure. With a single print of a grid pattern, an illuminator such as quadruple illuminator is typically used, which can have four openings as opposed to the two openings of the FIG. 11 dipole illuminator. However, the inventive process lends itself to the use of dipole illumination because the grid of features is formed using two separate exposures through spaces which extend in perpendicular directions. Thus dipole illumination can be used during each exposure using two dipole illuminators, with the axis of the openings of each illuminator being perpendicular to each other.

For reasons similar to those of dipole illumination, polarized light is not typically used in conventional processes to print a grid of features such as that depicted in FIG. 5. However, the present process can benefit from the use of polarized light due to the two exposures of the present process. Polarized light sources are conventionally used to print a single row or column of features.

Hole level critical dimension (CD) control can be improved due to a decreased effective mask error enhancement factor (MEEF) by printing the via opening or post at the intersection of two perpendicular spaces using two exposures rather than as a two-dimensional circular feature with a single print. With a single exposure print, a single mask illumination is used to form the via opening which, for photolithographic purposes, is a two-dimensional feature. At an NA greater than or equal to 0.8, any error in mask critical dimension has a large effect on the feature formed. By separately printing two perpendicular line spaces which, for photolithographic purposes, are one-dimensional features, mask error does not have as large of an affect on the resulting feature. Forming the two-dimensional via opening using reticles with perpendicular, one-dimensional line spaces results in a decreased MEEF. For a two-dimensional feature such as a via opening printed with a single exposure, MEEF is a factor of about 4 or greater (i.e. any error on the mask CD is magnified by four times in the photoresist when the photoresist is exposed). Printing the two-dimensional via opening using two one-dimensional line spaces decreases MEEF to a factor of about 1.

Additionally, the process margin can be improved with the present process which results from an increase exposure latitude (EL). With the present process, the EL is increased because the exposure energy and the focus are maximized. Additionally, the exposure latitude (EL) is increased with printing a one-dimensional line space rather than a two-dimensional via opening. The EL is a measure of how much the critical dimension (CD) of the feature varies with changes in focus and exposure energy. An increased EL indicates that the process is less sensitive to changes in focus and exposure energy which allows for increased process margin. With various embodiments the present process, the EL of the via opening increases because the one-dimensional line space pattern is less sensitive to variations in exposure energy and focus, and thus the two print via open CD is less sensitive to focus and exposure energy (or increased EL) compared with the single exposure print process used to form the two-dimensional via.

For the highest density via openings, the line space pattern on the reticle can be formed at a minimum contact pitch (MCP), which can result in maximum feature density.

The embodiments described above use a single development process to remove the latent image in the photoresist resulting from the first exposure along with the image resulting from the second exposure to form the final resist pattern of FIG. 5. Another embodiment of the invention can comprise a process employing two exposures to the light source and two exposures to a developer. During a first exposure to the light source, the photoresist can be exposed with the pattern similar to that depicted in FIG. 1. The light source can be a 193 nm wavelength source, and can be subject to at least one of polarization and dipole illumination, or an advanced technique as previously described which provides a minimum line space pitch. An illumination exposure energy is insufficient to fully convert the chemical makeup of the resist. In the present embodiment, an exposure energy of between about 55% and about 95%, more particularly between about 60% and about 90%, and most particularly about 75%, of that required to fully develop the resist can be used.

After exposing the photoresist layer to the light source and line space pattern of FIG. 1, the resist is exposed to a developer during a first development to only partially remove a portion of a thickness of the resist. The amount of the resist thickness removed is proportional to the exposure energy used to expose the pattern, with more of the photoresist thickness being removed as the exposure energy of the illumination source increases.

Subsequent to the first development, the photoresist can be exposed to a second pattern during a second illumination, for example to the line space pattern depicted in FIG. 2, having an axis which is perpendicular to the axis of the FIG. 1 line space pattern. As with the first exposure, an exposure energy is used which is insufficient to fully develop the photoresist, for example an energy does which is 75% of that required to fully develop the photoresist.

Next, the resist is exposed to a developer during a second development to only partially remove a first portion of the resist in first areas. In second areas, those areas 34 depicted in FIG. 3 which are exposed during both the first exposure and the second exposure, the second development completely removes the photoresist to expose the underlying layer.

After the second development, wafer processing can continue, for example according to the process depicted in FIGS. 6-10.

As with the previous embodiments, the light source can be subject to at least one of polarization and dipole illumination, or an advanced illumination technique as previously described which provides a minimum line space pitch. This results from the use of separate exposures of two one-dimensional features to form a two-dimensional feature.

It should be noted that other layers can be formed as a part of the semiconductor wafer substrate assembly than those depicted. For example, a bottom anti-reflective coating (BARC) layer or other methods to reduce reflection may be employed to reduce the reflected light to prevent standing waves which can cause waves in the resist pattern. Also, variations in the embodiments described above will be apparent to one of ordinary skill in the art.

While the process detailed above is described as a method used to form via openings (and resulting vias) in a dielectric layer using a positive photoresist and printing a line space, it will be appreciated that posts can be formed with a similar process which comprises the use of negative photoresist to print a line pattern rather than the line space pattern of FIGS. 1 and 2, or by using positive resist and a reticle having a pattern which is the opposite the reticle used to print the line space pattern of FIG. 1. In addition, various embodiments using positive and negative tone photoresist and positive or negative developer are contemplated.

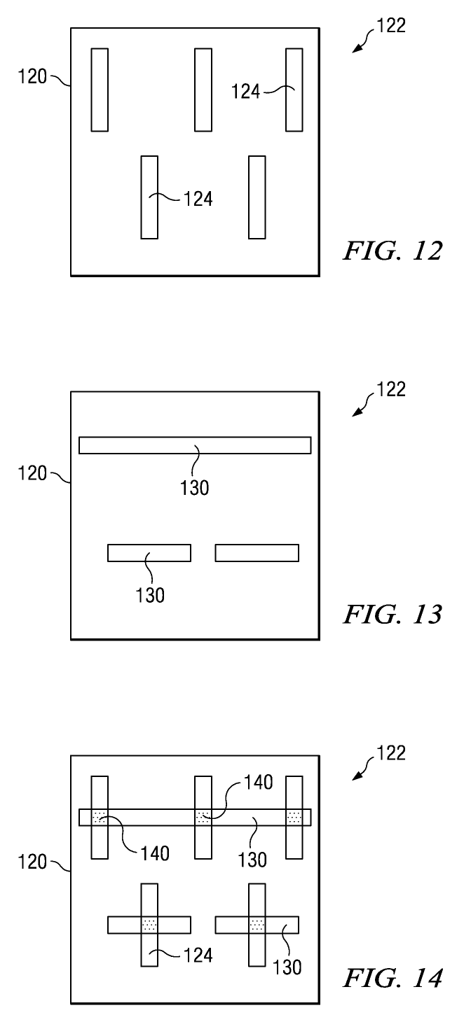

Further, the processes described above discloses the formation of a plurality of via openings arranged in a grid pattern, but data base decomposition or other methods can be employed to form isolated or random via openings or posts using two intersecting line spaces. For example, FIGS. 12-14 are plan views depicting an embodiment to form isolated via openings by printing line spaces using two exposures. FIG. 12 depicts a photosensitive layer (photoresist) 120 formed a part of a semiconductor wafer substrate assembly 122, which also comprises a layer to be etched (not individually depicted) below the photosensitive layer 120. A reticle is used to expose the photoresist to a first pattern 124 using a light source exposure energy which is insufficient to fully expose the photoresist. Next, another reticle is used to expose the photoresist to a second pattern 130 as depicted in FIG. 13 using a light source exposure energy which is insufficient to fully expose the photoresist. The first pattern 124 and the second pattern 130 intersect at locations 140 as depicted in FIG. 14. At intersecting locations 140, the combined exposure energy from the first and second exposures is sufficient to fully expose the photoresist at locations 140. Wafer processing may then continue, for example according to previous embodiments. Because the line spaces printed by each reticle are oriented in the same direction (vertical in FIG. 12 and horizontal in FIG. 13), the process can benefit from the use of dipole illumination or polarization of the light source.

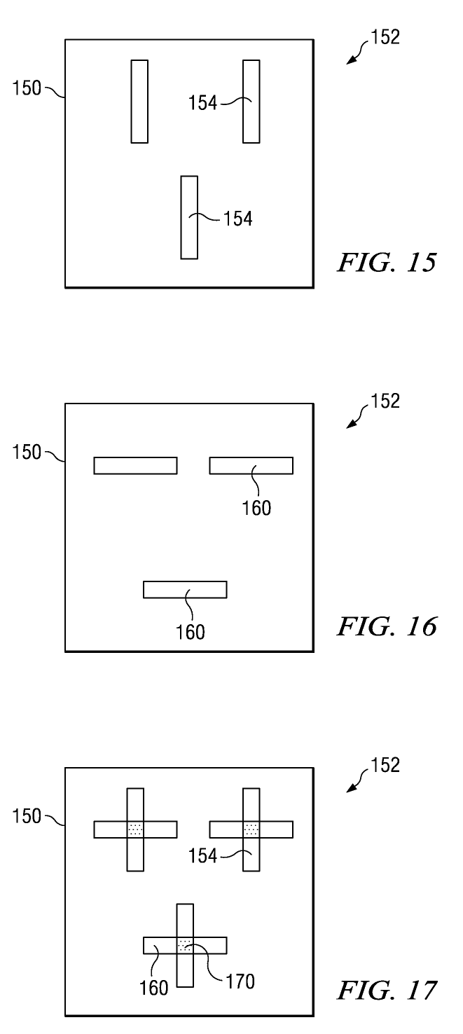

Similarly, FIGS. 15-17 are plan views depicting an embodiment to form random via openings by printing line spaces using two exposures. FIG. 15 depicts a photosensitive layer (photoresist) 150 formed a part of a semiconductor wafer substrate assembly 152, which also comprises a layer to be etched (not individually depicted) below the photosensitive layer 150. A reticle is used to expose the photoresist to a first pattern 154 using a light source exposure energy which is insufficient to fully expose the photoresist. Next, another reticle is used to expose the photoresist to a second pattern 160 as depicted in FIG. 16 using a light source exposure energy which is insufficient to fully expose the photoresist. The first pattern 154 and the second pattern 160 intersect at locations 170 as depicted in FIG. 17. At intersecting locations 170, the combined exposure energy from the first and second exposures is sufficient to fully expose the photoresist at locations 170. Wafer processing may then continue, for example according to previous embodiments. Because the line spaces printed by each reticle are oriented in the same direction (vertical in FIG. 15 and horizontal in FIG. 16), the process can benefit from the use of dipole illumination or polarization of the light source.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method used to form a semiconductor device, comprising:
exposing first portions of a photosensitive layer to a light source during only a first exposure with an exposure energy which is insufficient to fully expose the photosensitive layer;
exposing second portions of the photosensitive layer to the light source during only a second exposure with an exposure energy which is insufficient to fully expose the photosensitive layer; and
exposing third portions of the photosensitive layer to the light source during both the first and second exposures, wherein:
an exposure energy received by the third portions of the photosensitive layer during the first and second exposures is sufficient to fully expose the photosensitive layer, and
the light source is subject to an advanced illumination technique during at least one of the first and second exposures.

2. The method of claim 1, further comprising:
exposing a first line pattern during the first exposure;
exposing a second line pattern during the second exposure, wherein:
the first and second line patterns intersect: and the third portions of the photosensitive layer are located at the intersection of the first and second line patterns.

3. The method of claim 1, further comprising:
exposing a first line space pattern during the first exposure;
exposing a second line space pattern during the second exposure, wherein:
the first and second line space patterns intersect; and
the third portions of the photosensitive layer are located at the intersection of the first and second line space patterns.

4. The method of claim 1 further comprising removing the third portions of the photosensitive layer and leaving the first and second portions of the photosensitive layer.

5. The method of claim 1 further comprising removing the first and second portions of the photosensitive layer and leaving the third portions of the photosensitive layer.

6. The method of claim 1, wherein the advanced illumination technique includes at least one of dipole illumination and polarization.

7. A method used to form a semiconductor device, comprising:
using a light source to expose a first feature having a length and a width during a first exposure onto a photosensitive layer which overlies a layer to be etched, wherein the length of the first feature is longer than the width of the first feature and an exposure energy of the light source is insufficient to fully expose the photosensitive layer during the first exposure;
subsequent to exposing the first feature, using the light source to expose a second feature having a length and a width during a second exposure onto the photosensitive layer, wherein the length of the second feature is longer than the width of the second feature and an exposure energy of the light source is insufficient to fully expose the photosensitive layer during the second exposure; and
removing portions of the photosensitive layer to expose first portions of the layer to be etched and leaving portions of the photosensitive layer to cover second portions of the layer to be etched,
wherein the light source during at least one of the first and second exposures is subject to at least one of polarization and dipole illumination.

8. The method of claim 7 further comprising exposing at least one line during the first exposure and exposing at least one line during the second exposure.

9. The method of claim 8, further comprising exposing the at least one line during the second exposure perpendicular to the at least one line exposed during the first exposure.

10. The method of claim 7 further comprising exposing at least one line space during the first exposure and exposing at least one line space during the second exposure.

11. The method of claim 10, further comprising exposing the at least one line space during the second exposure perpendicular to the at least one line space exposed during the first exposure.

12. The method of claim 7, further comprising:
exposing first photosensitive layer portions to the light source only during the first exposure;
exposing second photosensitive layer portions to the light source only during the second exposure; and
exposing third photosensitive layer portions to the light source during both the first and second exposures.

13. The method of claim 12, further comprising removing the third photosensitive layer exposed portions to form an opening in the photosensitive layer and to expose the layer to be etched.

14. The method of claim 12, further comprising removing the first and second photosensitive layer exposed portions and leaving the third photosensitive layer portions covering the layer to be etched.

15. The method of claim 7, further comprising using the light source to expose the second pattern line or line space which extends in a direction perpendicular to the first pattern line or line space.

16. The method of claim 7, wherein the photosensitive layer is exposed at a proportionality constant of 0.4 or less during the first and second exposures.

17. The method of claim 7, wherein the exposure of the photosensitive layer to the light source during the first and second exposures further comprises exposing the photosensitive layer to a polarized light source.

18. The method of claim 7, wherein an exposure energy of the light source during the first exposure and during the second exposure are each between about 60% and about 90% of that required to fully expose the photosensitive layer.

19. The method of claim 7, wherein an exposure energy of the light source during the first exposure and during the second exposure are each about 75% of that required to fully expose the photosensitive layer.

20. The method of claim 7, further comprising:
subsequent to the first exposure and prior to the second exposure, removing first regions of the photosensitive layer and leaving second regions of the photosensitive layer.

21. The method of claim 7, wherein the advanced illumination technique includes at least one of dipole illumination and polarization.
